(19) United States
(12) Patent Application Publication
(10) Pub. No.: US 2010/0073986 A1
(43) Pub. Date: Mar. 25, 2010

(54) SEMICONDUCTOR MEMORY DEVICE

(75) Inventor: Susumu SHUTO, Yokohama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/553,895

(22) Filed: Sep. 3, 2009

(30) Foreign Application Priority Data
Sep. 24, 2008 (JP) 2008-244383

(51) Int. Cl. G11C 11/22; G11C 8/00; G11C 11/24

(52) U.S. Cl. 365/145; 365/230.03; 365/149

(57) ABSTRACT

A semiconductor memory device includes a plurality of cell blocks each of which is configured by serially connecting a plurality of memory cells each of which comprises a ferroelectric capacitor and a cell transistor connected in parallel; a plurality of word lines connected to gates of the cell transistors; a plurality of block selectors each of which comprises an enhancement transistor and a depletion transistor serially connected to each other; a plurality of bit lines connected via the block selectors to one ends of the cell blocks; and a plurality of plate lines connected to the other ends of the cell blocks, wherein a gate length of the enhancement transistor is longer than that of the depletion transistor.

### CROSS-REFERENCE TO RELATED APPLICATION

This application is based upon and claims the benefit of priority from the prior Japanese Patent Applications No. 2008-244383, filed on Sep. 24, 2008, the entire contents of which are incorporated herein by reference.

### BACKGROUND OF THE INVENTION

1. Field of the Invention

The present invention relates to a semiconductor memory device.

2. Related Art

“Series connected TC unit type ferroelectric RAM (hereinafter, also simply “ferroelectric memories”)” have been developed in recent years. The ferroelectric memory consists of series connected memory cells each having a transistor (T) having a source terminal and a drain terminal and a ferroelectric capacitor (C) inbetween said two terminals (Patent Documents 1 and 2).

The ferroelectric memory includes memory cell blocks. In each memory cell block, a plurality of the above memory cells are serially connected together. An end of the memory cell block is connected via a block selector to a bit line. The other end is connected to a plate line.

The block selector is provided for each memory cell block and includes an enhancement transistor (hereinafter, also “E-type transistor”) and a depletion transistor (hereinafter, also “D-type transistor”) (see FIG. 8). This is because either bit line BL or bBL is connected selectively to the corresponding memory cell block.

According to the progressing downscaling of recent years, gate lengths of the E-type transistor and the D-type transistor in the block selector become short. As the gate length of the E-type transistor is reduced, a cut-off characteristic of the E-type transistor becomes inferior. A leakage current through the block selector is thus increased. If the leakage current in the block selector is increased, data stored in unselected memory cells can be broken during data writes or reads.

To reduce a leakage current, a threshold voltage of the E-type transistor can be set to be high. A channel impurity density of the E-type transistor is usually determined during the same implantation step as the one for the cell transistor in the memory cell for simplifying a manufacturing method. Thus, if the threshold voltage of the E-type transistor is increased, the threshold voltage of the cell transistor can be also increased. This reduces a current drive capability of the cell transistor, resulting in reduced read/write operation rate. Changing the channel impurity densities of the E-type transistor and the cell transistor can lead to an increased number of manufacturing steps, resulting in increased costs.

### SUMMARY OF THE INVENTION

A semiconductor memory device according to an embodiment of the present invention comprises: a plurality of cell blocks each of which is configured by serially connecting a plurality of memory cells each of which comprises a ferroelectric capacitor and a cell transistor connected in parallel; a plurality of word lines connected to gates of the cell transistors; a plurality of block selectors each of which comprises an enhancement transistor and a depletion transistor serially connected to each other; a plurality of bit lines connected via the block selectors to one ends of the cell blocks; and a plurality of plate lines connected to the other ends of the cell blocks, wherein a gate length of the enhancement transistor is longer than that of the depletion transistor.

### BRIEF DESCRIPTION OF THE DRAWINGS

FIG. 1 shows a configuration of a ferroelectric memory according to a first embodiment of the present invention;

FIG. 2 is a diagram showing an internal configuration of a part defined by a broken line frame shown in FIG. 1;

FIG. 3 is a layout diagram showing configurations of the block selectors BSP0 to BSP3 and their peripheral parts;

FIG. 4 is a cross-sectional view along a line 4-4 shown in FIG. 3;

FIG. 5 is a layout diagram showing a modified example of the first embodiment;

FIG. 6 is a circuit diagram showing an internal configuration of a ferroelectric memory according to a second embodiment;

FIG. 7 is a layout diagram showing configurations of the block selectors BSP0 to BSP3 and their peripheral parts in the second embodiment; and

FIG. 8 is a layout diagram showing configurations of the block selectors BSP0 to BSP3 and their peripheral parts in a comparative example.

### DETAILED DESCRIPTION OF THE INVENTION

Embodiments of the present invention will be explained below in detail with reference to the accompanying drawings. Note that the invention is not limited thereto.

### First Embodiment

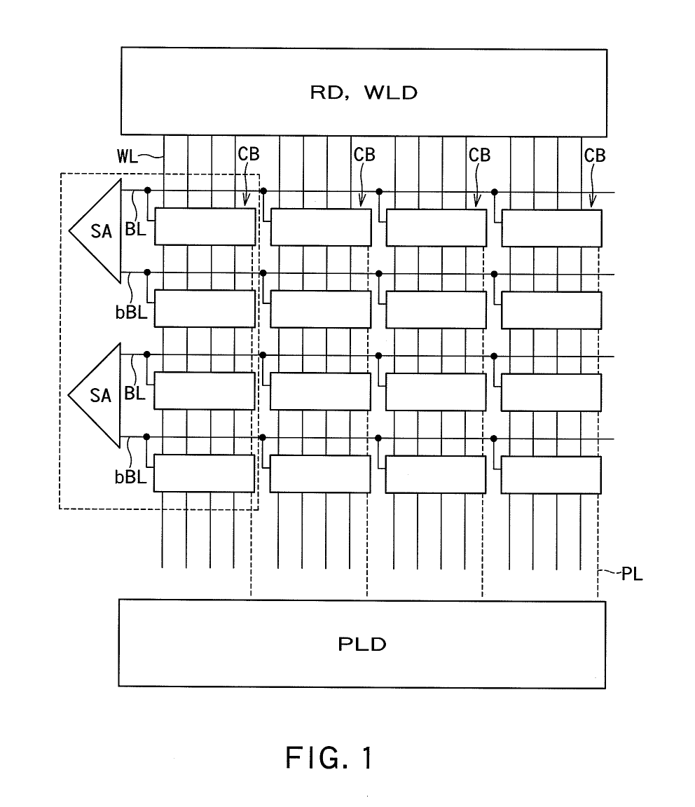

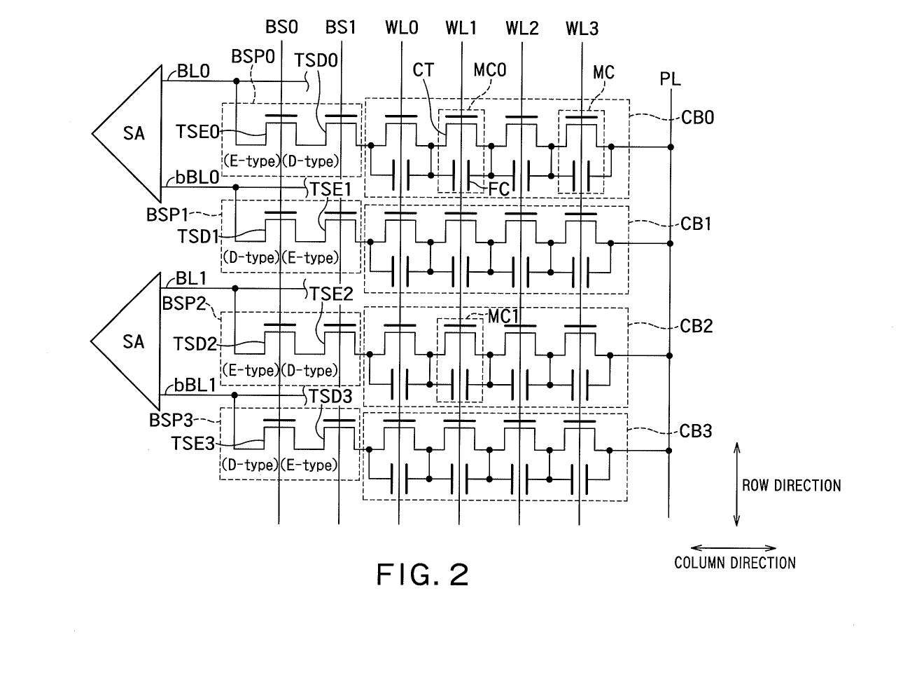

FIG. 1 shows a configuration of a ferroelectric memory according to a first embodiment of the present invention. FIG. 2 is a diagram showing an internal configuration of a part defined by a broken line frame shown in FIG. 1. The ferroelectric memory of the first embodiment includes a plurality of word lines WL extending in a row direction, a plurality of bit lines BL extending in a column direction perpendicular to the row direction, and a plurality of plate lines PL extending in the row direction. The plate lines PL are shown by broken lines in FIG. 1 so as to be distinguished from the word lines WL. A block selector is omitted in FIG. 1.

Cell blocks CB including a plurality of memory cells MC are arranged two-dimensionally in a matrix. A memory cell MC stores binary data or multibit data in a ferroelectric capacitor. The memory cell MC is formed on a semiconductor substrate. The memory cell MC is provided at the intersection of the word line WL and the bit line BL or bBL. Each word line WL is provided for the memory cells MC arranged in the row direction. Each bit line BL or bBL is provided for the memory cells MC arranged in the column direction. The plate lines PL are provided for the cell blocks arranged in the row direction.

A word line drive circuit WLD is connected to the word lines WL. The word line drive circuit WLD selects a part of the word lines WL (singular or plural) according to addresses received from a row decoder RD and inactivates the selected word lines WL. A sense amplifier SA is connected to a bit line pair BL and bBL. The sense amplifier SA detects data from memory cells transmitted through the bit line pair BL and bBL during data reads. The sense amplifier SA applies voltage to the bit line pair BL and bBL during data writes. Thus, the sense amplifier SA can read or write data from or in the memory cells MC connected to the selected word line.

While FIG. 1 shows the cell blocks CB arranged in a 4×4 matrix, the number of the cell blocks CB is not limited thereto.

As shown in FIG. 2, the ferroelectric memory of the first embodiment is a series connected TC unit type ferroelectric RAM.

The ferroelectric memory of the first embodiment operates in a 1T1C mode. In the 1T1C mode, only one of bit lines BL and bBL connected to the sense amplifier SA is connected to the sense amplifier SA. The other bit line is disconnected from the sense amplifier SA and transmits reference data used for detecting the data from memory cells MC. The sense amplifier SA detects a logical value of the data from the one bit line based on the reference data from the other bit line. The reference data has the intermediate potential between data “1” and data “0”. In the 1T1C mode, each memory cell MC can store 1 bit data. A folded bit line structure is utilized in the first embodiment.

The ferroelectric memory includes a plurality of cell blocks CB0 to CB3 each of which is configured by serially connecting memory cells MC each of which includes a ferroelectric capacitor FC and the cell transistor CT connected in parallel. Word lines WL0 to WL3 are connected to gates of the cell transistors CT in the respective memory cells MC.

One ends of the cell blocks CB0 to CB3 are connected to one ends of block selectors BSP0 to BSP3, respectively. The other ends of the cell blocks CB0 to CB3 are connected to the plate line PL. The other ends of the block selectors BSP0 to BSP3 are connected to the bit lines BL0, bBL0, BL1, and bBL1, respectively. Namely, the bit lines BL0, bBL0, BL1, and bBL1 are connected via the respective block selectors BSP0 to BSP3 to the cell blocks CB0 to CB3. As described above, the one ends of the cell blocks CB0 to CB3 sharing the word lines WL0 to WL3 are connected via the different block selectors BSP0 to BSP3 to the different bit lines BL0, bBL0, BL1, and bBL1 in the first embodiment. The cell blocks CB0 to CB3 share the plate line PL.

The block selectors BSP0 to BSP3 include E-type transistors and D-type transistors serially connected between the respective cell blocks CB0 to CB3 and the bit lines BLi or bBLi (i is an integer). The E-type transistor becomes conductive (on) by driving a gate potential. The D-type transistor is conductive (on) regardless of the gate potential.

The block selector BSP0 has an E-type transistor TSE0 and a D-type transistor TSD0 serially connected to each other between the bit line BL0 and the cell block CB0. The E-type transistor TSE0 is provided on the bit line BL0 side, while the D-type transistor TSD0 is provided on the cell block CB0 side. The block selector BSP1 has an E-type transistor TSE1 and a D-type transistor TSD1 serially connected to each other between the bit line bBL0 and the cell block CB1. The D-type transistor TSD1 is provided on the bit line BL side, while the E-type transistor TSE1 is provided on the cell block CB0 side.

The block selector BSP2 has an E-type transistor TSE2 and a D-type transistor TSD2 serially connected to each other between the bit line BL1 and the cell block CB2. The E-type transistor TSE2 is provided on the bit line BL1 side, while the D-type transistor TSD2 is provided on the cell block CB2 side. The block selector BSP3 has an E-type transistor TSE3 and a D-type transistor TSD3 serially connected between the bit line bBL1 and the cell block CB3. The D-type transistor TSD3 is provided on the bit line bBL1 side, while the E-type transistor TSE3 is provided on the cell block CB3 side.

Gates of the transistors TSE0, TSD1, TSE2, and TSD3 are connected to the block selection line BS0. The transistors TSE0, TSD1, TSE2, and TSD3 are controlled by signals from the block selection line BS0. Gates of the transistors TSD0, TSE1, TSD2, and TSE3 are connected to the block selection line BS1. The transistors TSD0, TSE1, TSD2, and TSE3 are controlled by signals from the block selection line BS1. In an ordinary operation, either the block selection line BS0 or BS1 is activated. Namely, not both of the block selection lines BS0 and BS1 are activated to be in a logical high state in the ordinary operation. The selection lines BS0 and BS1 transmit complementary logical signals or are inactivated to be in a logical low state.

The positional relationship between the E-type transistor and the D-type transistor in the block selector BSP0 is opposite to the one in the block selector BSP1. When the block selection line BS0 is activated, the E-type transistor TSE0 is turned on, while the E-type transistor TSE1 is turned off. The cell block CB0 is thus connected via the block selector BSP0 to the bit line BL0. The cell block CB1 is disconnected from the bit line bBL0. At this time, any of the memory cells MC in the cell block CB0 is connected to the bit line BL0 and the data of that memory cell MC is transmitted to the bit line BL0. The reference data is transmitted to the bit line bBL0. The sense amplifier SA detects the logical value of the data from the bit line BL0 by using the reference data from the bit line bBL0 as a standard.

For example, when the word line WL1 is selected, only the selected word line WL1 is inactivated to be in a logical low state. Other word lines WL0, WL2, and WL3 maintain an activated state. At this time, if the block selection line BS0 is activated, the ferroelectric capacitor FC of the memory cell MC0 is connected between the bit line BL0 and the plate line PL and the ferroelectric capacitor FC of the memory cell MC1 is connected between the bit line BL1 and the plate line PL. Thus, the sense amplifier SA can detect the data of the memory cells MC0 and MC1.

The reference data can be generated by using a plurality of dummy cells storing data “0” and “1” in advance. Alternatively, the reference data can also be generated outside the memory cell array.

On the other hand, when the block selection line BS1 is activated, the cell block CB1 is connected via the block selector BSP1 to the bit line bBL0. The cell block CB0 is disconnected from the bit line BL0. The block selectors BSP0 and BSP1 can connect selectively either the cell block CB0 or CBS to the bit line BL. Any of the memory cells MC in the cell block CB1 is connected to the bit line bBL0 and the data of that memory cell MC is transmitted to the bit line bBL0. The reference data is transmitted to the bit line BL0. The sense amplifier SA detects the logical value of the data from the bit line bBL0 by using the reference data from the bit line BL0 as a standard.

The positional relationship between the E-type transistor and the D-type transistor in the block selector BSP2 is also opposite to the one in BSP3. The block selectors BSP2 and BSP3 can connect either the cell block CB2 or CB3 selectively to the bit line BL1 or bBL1. Because operations of the cell blocks CB2 and CB3 are the same as in the cell blocks CB0 and CB1, descriptions thereof will be omitted.

Activation means turning on or driving devices or circuits. Inactivation means turning off or stopping devices or circuits. Thus, it should be noted that HIGH (high potential level) signals can be activated signals or LOW (low potential level) signals can be activated signals. For example, NMOS transistors are activated by making the gates HIGH. On the other hand, PMOS transistors are activated by making the gates LOW.

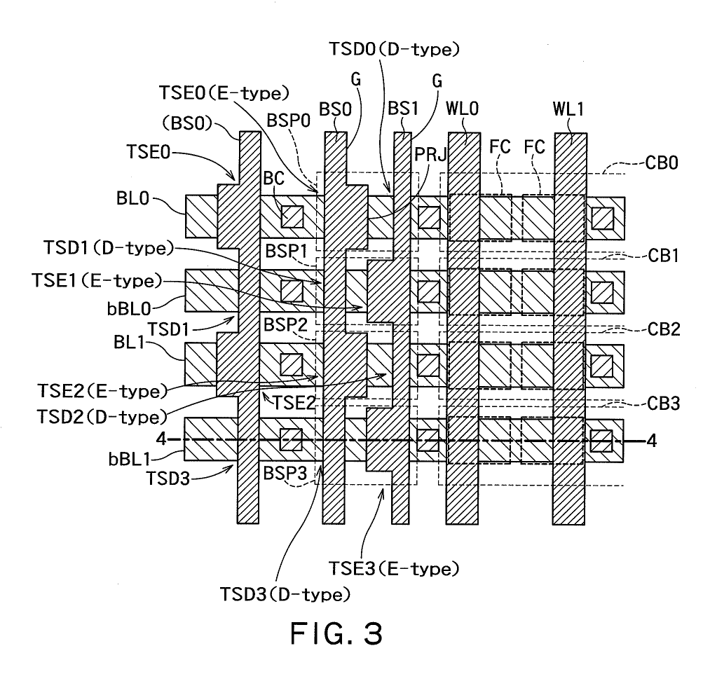

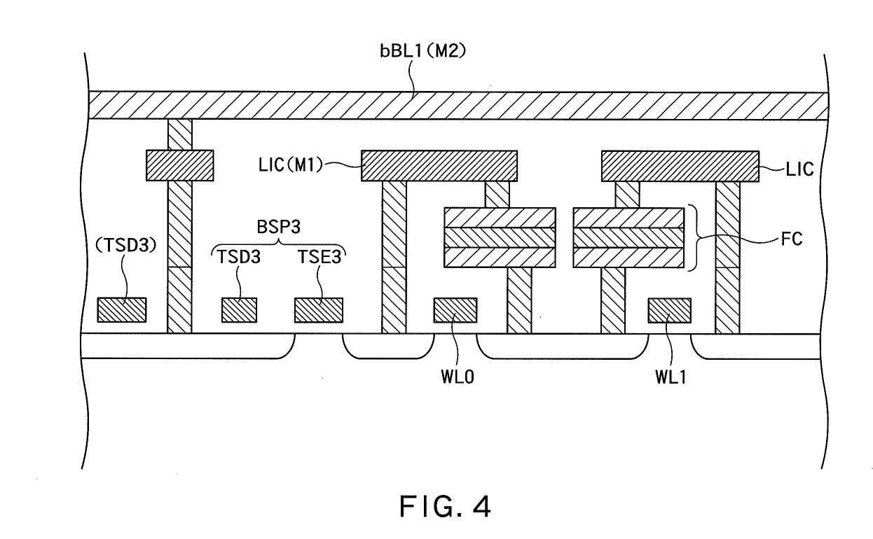

FIG. 3 is a layout diagram showing configurations of the block selectors BSP0 to BSP3 and their peripheral parts. FIG. 4 is a cross-sectional view along a line 4-4 shown in FIG. 3. The E-type transistors TSE0 to TSE3 are formed so as to have longer gate lengths than those of the D-type transistors TSD0 to TSD3. The block selection lines BS0 and BS1 (gate electrodes for the E-type transistors TSE0 to TSE3 and the D-type transistors TSD0 to TSD3) are formed in a comb shape so as to have irregularities as seen from a plain surface. The block selection lines BS0 and BS1 are patterned so that their comb-shaped projections PRJ are opposed alternately and are engaged. The projection PRJ of the block selection line BS0 projects into the concave of the block selector BS1 in the column direction. The projection PRJ of the block selection line BS1 projects into the concave of the block selector BS0 in the column direction. Namely, the block selection line BS0 and the block selection line BS1 are projected alternately for every column.

Because the E-type transistors TSE0 to TSE3 are formed so as to have longer gate lengths, an off leakage current can be kept low even if the block selectors BSP0 to BSP3 are downscaled. As a result, the reliability of the ferroelectric memory is improved. While the gate lengths of the D-type transistors TSD0 to TSD3 are made short, it does not matter because the D-type transistors TSD0 to TSD3 are always on.

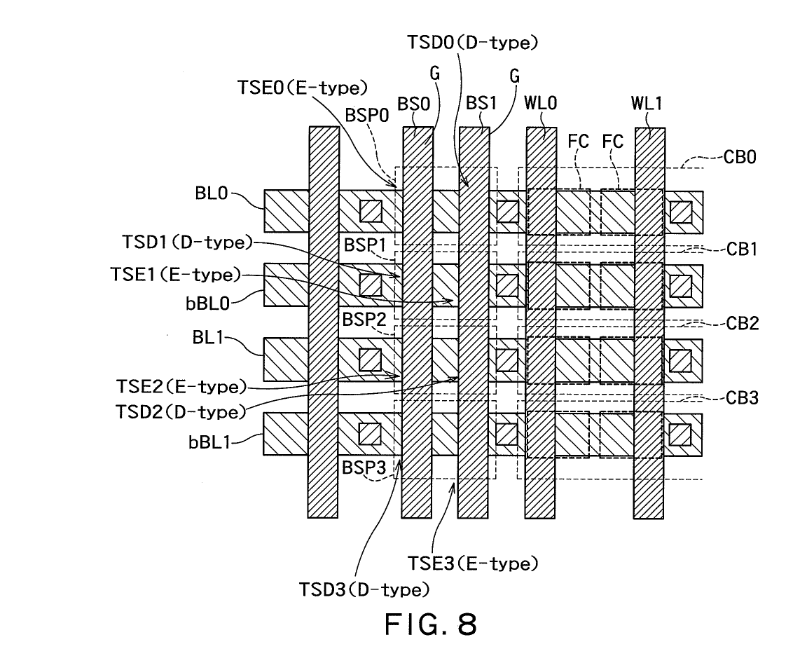

According to a comparative example shown in FIG. 8, the gate lengths of the E-type transistors TSE0 to TSE3 are the same as those of the D-type transistors TSD0 to TSD3. Assume that the sum of column direction widths of the block selection lines BS0 and BS1 in the comparative example is equal to the one in the first embodiment. In this case, the gate lengths of the E-type transistors TSE0 to TSE3 in the comparative example are shorter than those of the first embodiment. In the block selection lines BS0 and BS1 of the comparative example, an off leakage current is thus larger than that of the first embodiment.

In the first embodiment, the gate lengths of the E-type transistors TSE0 to TSE3 and the D-type transistors TSD0 to TSD3 can be determined by using the gate length of the cell transistor CT in the memory cell MC as a standard. For example, the gate lengths of the E-type transistors TSE0 to TSE3 are set to be longer than that of the cell transistor CT. The gate lengths of the D-type transistors TSD0 to TSD3 are set to be shorter than that of the cell transistor CT. Thus, effects of the first embodiment can be accomplished.

Channel impurity densities of the E-type transistors TSE0 to TSE3 and the D-type transistors TSD0 to TSD3 are substantially equal to that of the cell transistor. Thus, channels of the cell transistor CT and channels of the transistors in the block selector BSP can be formed by the same step. As a result, changing photomask patterns for lithography in existing manufacturing processes when forming the block selection lines BS0 and BS1 will suffice for the ferroelectric memory of the first embodiment.

The sums of gate lengths of the E-type transistors TSE0 to TSE3 and the D-type transistors TSD0 to TSD3 are fixed, respectively. While the space between the block selection lines BS0 and BS1 is made zigzag, its column direction width is fixed. The column direction widths of the block selectors BSP0 to BSP3 are thus fixed. Namely, the column direction widths of the block selectors BSP0 to BSP3 can be equal to those of the block selectors for the conventional ferroelectric memory shown in FIG. 8 in the same generation, while keeping the gate lengths of the E-type transistors TSE0 to TSE3 long. Because the first embodiment does not increase a chip area, the cost of the chip is not affected.

### Modified Example of First Embodiment

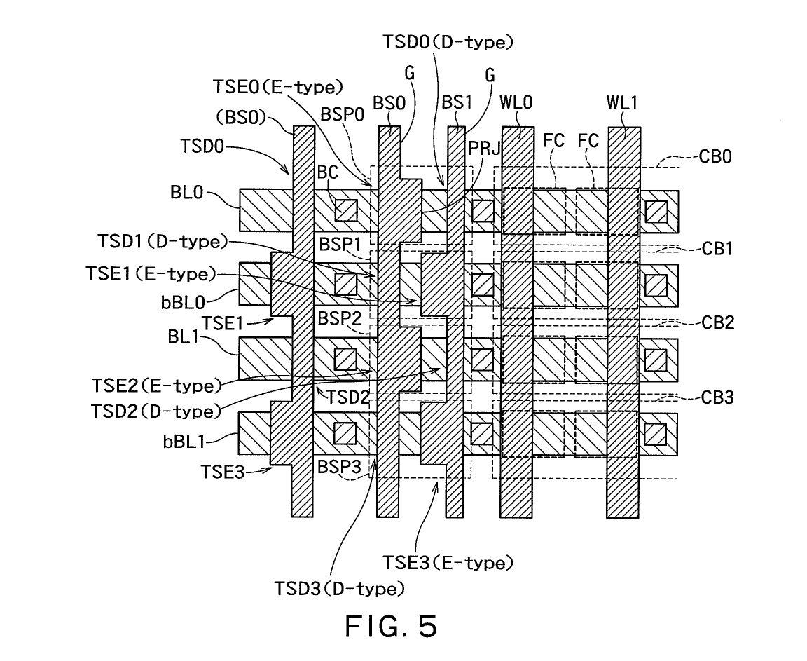

FIG. 5 is a layout diagram showing a modified example of the first embodiment. When two cell blocks CB adjacent to each other in the column direction share a bit line contact BC, as shown in FIG. 5, bit select lines BS0 and (BS0) for the two adjacent cell blocks CB is arranged so as to sandwich the bit line contact BC. One of the bit select lines for the adjacent cell blocks CB is indicated by (BS0).

When the E-type transistors TSEi of the bit select lines BS0 and (BS0) are adjacent to each other and the D-type transistors TSDi of the bit select lines BS0 and (BS0) are adjacent to each other as shown in FIG. 3, the capacitance of the bit line BLi is different greatly from that of the bit line bBLi. This is because only the capacitance of two E-type transistors TSEi is applied to the bit line BLi, while the capacitances of two D-type transistors TSDi and two E-type transistors TSEi are applied to the bit line bBLi under an unselected state.

On the other hand, according to the modified example shown in FIG. 5, the E-type transistor TSEi for one of the bit select lines BS0 and (BS0) is adjacent to the D-type transistor TSDi for the other of the bit select lines. The capacitance of the bit line BLi is thus substantially equal to that of the bit line bBLi. Variations in signal amount can be thus suppressed in the bit lines BL and bBL.

### Second Embodiment

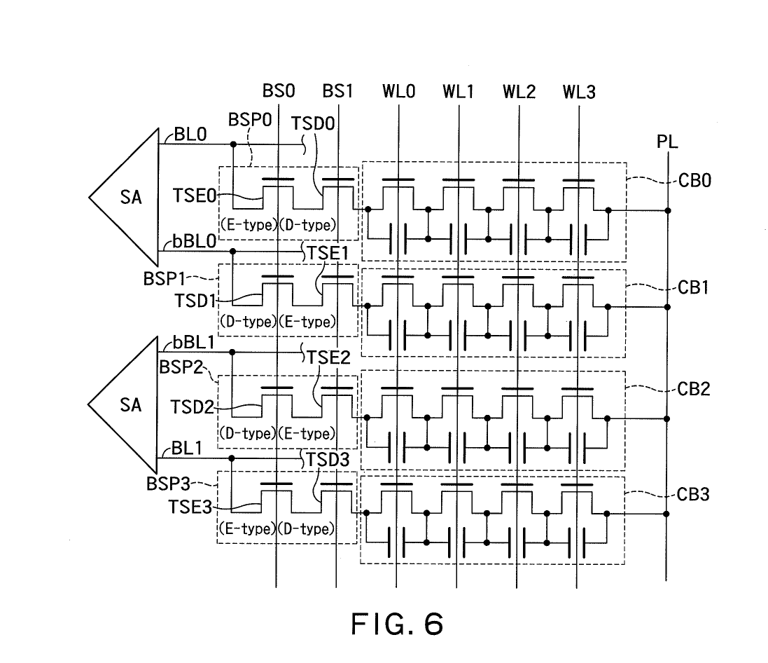

FIG. 6 is a circuit diagram showing an internal configuration of a ferroelectric memory according to a second embodiment. Because the overall configuration of the ferroelectric memory is the same as the one in FIG. 1, descriptions thereof will be omitted. The bit line pairs BLi and bBLi connected to each sense amplifier SA are arranged to be opposite to each other in two adjacent sense amplifiers SA in the second embodiment. Namely, two bit lines BLi and two bit lines bBLi are arranged alternately. For example, the bit lines are arranged in the order of BL0, bBL0, bBL1, BL1, BL2, bBL2, bBL3, BL3 . . . BLn, BLn+1, bBLn+1, bBLn+2 . . . .

The block selector whose enhancement transistor TSE is connected to the bit line side and whose depletion transistor TSD is connected to the cell block side is called a first block selector. The block selector whose depletion transistor TSD is connected to the bit line side and whose enhancement transistor TSE is connected to the cell block side is called a second block selector. In this case, two first block selectors and two second block selectors are arranged alternately in the row direction. Other configurations of the second embodiment can be identical to those of the first embodiment.

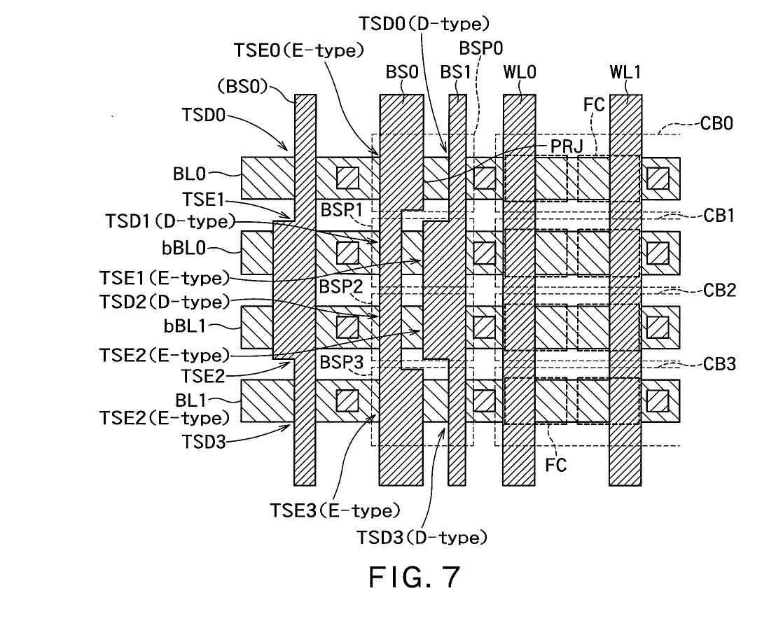

FIG. 7 is a layout diagram showing configurations of the block selectors BSP0 to BSP3 and their peripheral parts in the second embodiment. Because two first block selectors and two second block selector are arranged alternately, the row direction width of the projection PRJ provided in the selection lines BS0 and BS1 is increased. The total number of the projections PRJ for the block selection lines BS0 and BS1 is thus reduced. Because an electric field tends to be focused upon the edge of the projection PRJ, the reduced number of the projections PRJ is preferable to improve the reliability.

Because the irregularities of the block selection lines BS0 and BS1 are reduced, inferior patterning of the block selection lines BS0 and BS1 by lithography can be suppressed. Further, the same effects as those of the first embodiment can be achieved in the second embodiment.

When two cell blocks CB adjacent to each other in the column direction share the bit line contact BC, as shown in FIG. 7, the bit select lines BS0 and (BS0) for the two adjacent cell block CB are also arranged so as to sandwich the bit line contact BC in the second embodiment. As shown in FIG. 7, the E-type transistor TSEi for one of the bit select lines BS0 and (BS0) is adjacent to the D-type transistor TSDi for the other bit select line in the second embodiment. Therefore, the capacitance of the bit line BLi is substantially equal to that of the bit line bBLi, and thus variations in signal amount are suppressed in the bit lines BL and bBL.

The above embodiments relate to the ferroelectric memory operating in the 1T-1C mode. The above embodiments can be applied to also ferroelectric memories operating in a 2T-2C mode. In this case, two memory cells MC sharing a word line and connected to bit line pairs BL and bBL store complementary data (data “1” and data “0”) and the complementary data is processed as 1 bit data. When detecting data, two pieces of the complementary data stored in the two memory cells MC sharing a word line and connected to the bit line pairs BL and bBL are detected simultaneously as the 1 bit data. The sense amplifier SA detects one of the data transmitted in the bit line pairs BL and bBL by using the other data as reference data. Two enhancement transistors in each of two block selectors connected to each sense amplifier SA are connected to the same block selection line BS (e.g., BL0). Two depletion transistors in each of the two block selectors are connected to other same block selection line BS (e.g., BL1). With this configuration, the same effects as those of the first and the second embodiments can be achieved even in the ferroelectric memory operating in the 2T-2C mode.

1. A semiconductor memory device comprising:
a plurality of cell blocks each of which is configured by serially connecting a plurality of memory cells each of which comprises a ferroelectric capacitor and a cell transistor connected in parallel;
a plurality of word lines connected to gates of the cell transistors;
a plurality of block selectors each of which comprises an enhancement transistor and a depletion transistor serially connected to each other;
a plurality of bit lines connected via the block selectors to one ends of the cell blocks; and
a plurality of plate lines connected to the other ends of the cell blocks, wherein
a gate length of the enhancement transistor is longer than that of the depletion transistor.

2. The device of claim 1, wherein
the gate length of the enhancement transistor is longer than that of the cell transistor, and
the gate length of the depletion transistor is shorter than that of the cell transistor.

3. The device of claim 1, wherein
the block selectors comprise a first block selector that the enhancement transistor is connected to the bit line and the depletion transistor is connected to the cell block and a second block selector that the depletion transistor is connected to the bit line and the enhancement transistor is connected to the cell block, and
two first block selectors and two second block selectors are arranged alternately in a direction the word line extends.

4. The device of claim 2, wherein
the block selectors comprise a first block selector that the enhancement transistor is connected to the bit line and the depletion transistor is connected to the cell block and a second block selector that the depletion transistor is connected to the bit line and the enhancement transistor is connected to the cell block, and
two first block selectors and two second block selectors are arranged alternately in a direction the word line extends.

5. The device of claim 1, wherein a channel impurity density of the enhancement transistor is substantially equal to that of the cell transistor.

6. The device of claim 2, wherein a channel impurity density of the enhancement transistor is substantially equal to that of the cell transistor.

7. The device of claim 3, wherein a channel impurity density of the enhancement transistor is substantially equal to that of the cell transistor.

8. The device of claim 1, wherein the sum of gate lengths of the enhancement transistor and the depletion transistor is substantially the same for the respective block selectors.

9. The device of claim 2, wherein the sum of gate lengths of the enhancement transistor and the depletion transistor is substantially the same for the respective block selectors.

10. The device of claim 3, wherein the sum of gate lengths of the enhancement transistor and the depletion transistor is substantially the same for the respective block selectors.

11. The device of claim 1, wherein
the block selector comprises two gate wirings corresponding to the enhancement transistor and the depletion transistor, respectively,
the two gate wirings are made in a comb shape and arranged in such a manner that their comb shaped projections oppose to each other alternately.

12. The device of claim 2, wherein
the block selector comprises two gate wirings corresponding to the enhancement transistor and the depletion transistor, respectively,
the two gate wirings are made in a comb shape and arranged in such a manner that their comb shaped projections oppose to each other alternately.

13. The device of claim 3, wherein
the block selector comprises two gate wirings corresponding to the enhancement transistor and the depletion transistor, respectively,
the two gate wirings are made in a comb shape and arranged in such a manner that their comb shaped projections oppose to each other alternately.

14. The device of claim 1, wherein the enhancement transistor of one of two adjacent block selectors is adjacent to the depletion transistor of the other block selector.

15. The device of claim 2, wherein the enhancement transistor of one of two adjacent block selectors is adjacent to the depletion transistor of the other block selector.

16. The device of claim 3, wherein the enhancement transistor of one of two adjacent block selectors is adjacent to the depletion transistor of the other block selector.
